(19) United States
(12) Patent Application Publication
(10) Pub. No.: US 2024/0365497 A1
(43) Pub. Date: Oct. 31, 2024

(54) Server System Configurable Bay Device Mounting System

(71) Applicant: Dell Products L.P., Round Rock, TX (US)

(72) Inventors: Owen Kidd, Cedar Park, TX (US); Walter R. Carver, Round Rock, TX (US)

(73) Assignee: Dell Products L.P., Round Rock, TX (US)

(21) Appl. No.: 18/138,761

(22) Filed: Apr. 25, 2023

(51) Int. Cl. H05K 7/14

(52) U.S. Cl. CPC H05K 7/1487; H05K 7/1489

(57) ABSTRACT

A configurable bay device mounting system. The configurable bay device mounting system includes a device bay, the device bay being defined by a first side wall, a second side wall, a top plate and a bottom plate, the device bay being configurable to mount a plurality of devices conforming to one or both of a first form factor and a second form factor. In certain embodiments, the first form factor corresponds to an enterprise and datacenter standard form factor (EDSFF) E3 form factor and the second form factor corresponds to an EDSFF E1 form factor.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing configurable drive bay device mounting. In certain embodiments, the configurable drive bay device mounting is provided via a configurable bay device mounting system.

In one embodiment, the invention relates to a configurable bay device mounting system, comprising: a device bay, the device bay, the device bay being defined by a first side wall, a second side wall a top plate and a bottom plate, the device bay being configurable to mount a plurality of devices conforming to one or both of a first form factor and a second form factor.

In another embodiment, the invention relates to a system comprising: a processor; a data bus coupled to the processor; and, a configurable bay device mounting system, comprising: a device bay, the device bay, the device bay being defined by a first side wall, a second side wall a top plate and a bottom plate, the device bay being configurable to mount a plurality of devices conforming to one or both of a first form factor and a second form factor.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A and 4B, generally referred to as FIG. 4, show front views of a server type information handling system having a configurable bay device mounting system.

FIGS. 5A and 5B, generally referred to as FIG. 5, show rear perspective views of a server type information handling system having a configurable bay device mounting system.

FIGS. 6A and 6B, generally referred to as FIG. 6, show front rear perspective views of a server type information handling system having a configurable bay device mounting system.

FIG. 7 shows a rear perspective view of a server type information handling system having a configurable bay device mounting system.

FIG. 8A, generally referred to as FIG. 8, shows a front perspective view of a server type information handling system having a configurable bay device mounting system.

FIG. 8B, generally referred to as FIG. 8, shows a front perspective view of a server type information handling system having a configurable bay device mounting system.

### DETAILED DESCRIPTION

Various aspects of the disclosure include an appreciation that it is often desirable to provide an information handling system, especially server type information handling systems with a bay capable of receiving drives corresponding to an enterprise and datacenter standard form factor (EDSFF). Various aspects of the disclosure include an appreciation that the EDSFF disk form factor standard generally provides for two primary disk sizes, an E1 disk size and an E3 disk size. One of these formats is short and wide, while the other is tall and narrow. Various aspects of the disclosure include an appreciation that a comparable number of disks, either E1 disks or E3 disks, can fit in the same space when arranged optimally, however the E1 and E3 form-factors cannot co-exist at the same density when using the same disk bay mechanicals.

A system and method are disclosed for providing configurable drive bay device mounting. In certain embodiments, the configurable drive bay device mounting is provided via a configurable bay device mounting system. In certain embodiments, the configurable drive bay device mounting includes backplane-decoupled disk bay mechanical inserts to optimally arrange the EDSFF disk form factors on a server front end. The backplane-decoupled scheme allows any type of backplane to be installed regardless of which insert is assembled.

In certain embodiments, the configurable bay device mounting system includes disk bay inserts which slide into place inside the disk bay space. These inserts function like removable dividing partitions which are secured into place with an appropriate number of grooves, notches, and latching features which would be common between the insert mechanicals. In certain embodiments, the configurable drive bay device mounting system also includes backplane attachment features associated with respective device bay drive configurations. These backplane attachment features of the disk bay space would not dictate which disk bay inserts could be installed. These two design aspects are independent of each other. The configurable bay device mounting system enables swappable chassis front ends which enable exchange of entire disk bay spaces including backplane mechanicals.

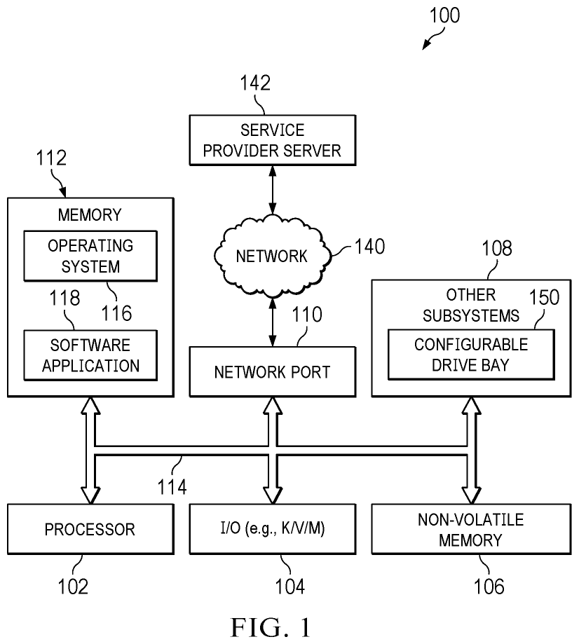

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include an OCP FLOP retention system 150 and an OCP card mounting system 152. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

A system and method are disclosed for providing configurable drive bay device mounting. In certain embodiments, the configurable drive bay device mounting is provided via a configurable bay device mounting system. In certain embodiments, the configurable drive bay device mounting includes backplane-decoupled disk bay mechanical inserts to optimally arrange the EDSFF disk form factors on a server front end. The backplane-decoupled scheme allows any type of backplane to be installed regardless of which insert is assembled.

In certain embodiments, the configurable bay device mounting system includes disk bay inserts which slide into place inside the disk bay space. These inserts function like removable dividing partitions which are secured into place with an appropriate number of grooves, notches, and latching features which would be common between the insert mechanicals. In certain embodiments, the configurable drive bay device mounting system also includes backplane attachment features associated with respective device bay drive configurations. These backplane attachment features of the disk bay space would not dictate which disk bay inserts could be installed. These two design aspects are independent of each other. The configurable bay device mounting system enables swappable chassis front ends which enable exchange of entire disk bay spaces including backplane mechanicals.

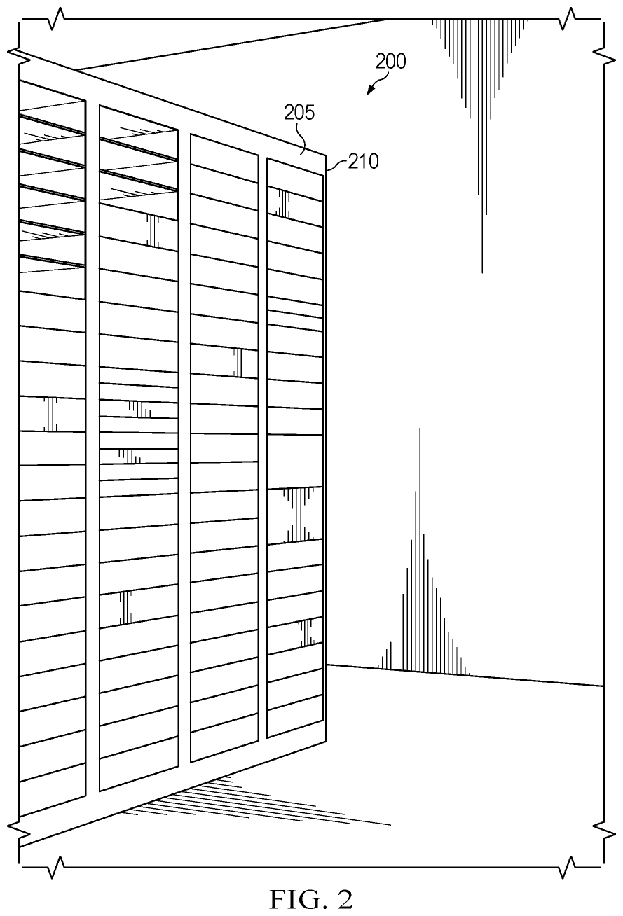

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1 U rack unit, a 2 U rack unit and a 4 U rack unit. In general, a 1 U rack unit is substantially (i.e., +/−20%) 1.75″ high, a 2 U rack unit is substantially (i.e., +/−20%) 3.5″ high and a 4 U rack height is substantially (i.e., +/−20%) 7.0″ high.

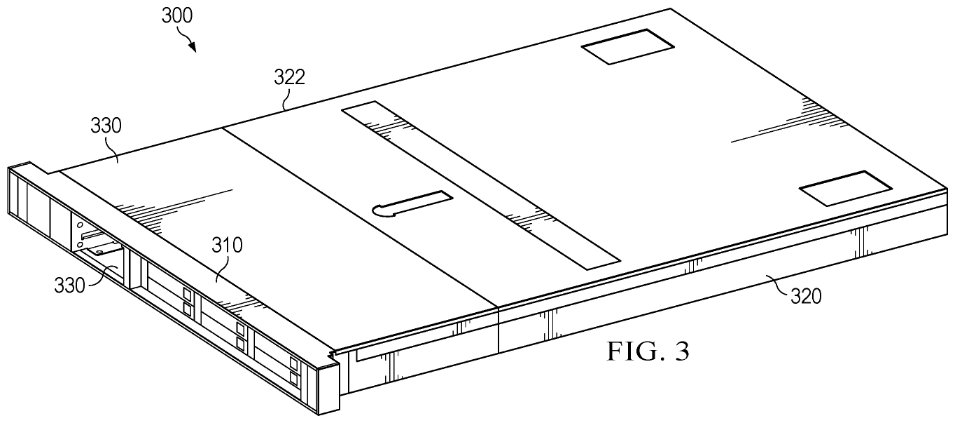

FIG. 3 shows a generalized perspective view of an example rack server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the rack type information handling system 300 may be accessed by removing a top panel 330 of the rack type information handing system 300. In certain embodiments, the rack type information handing system 300 includes a bay 350 via which components may be mounted to the rack type information handling system.

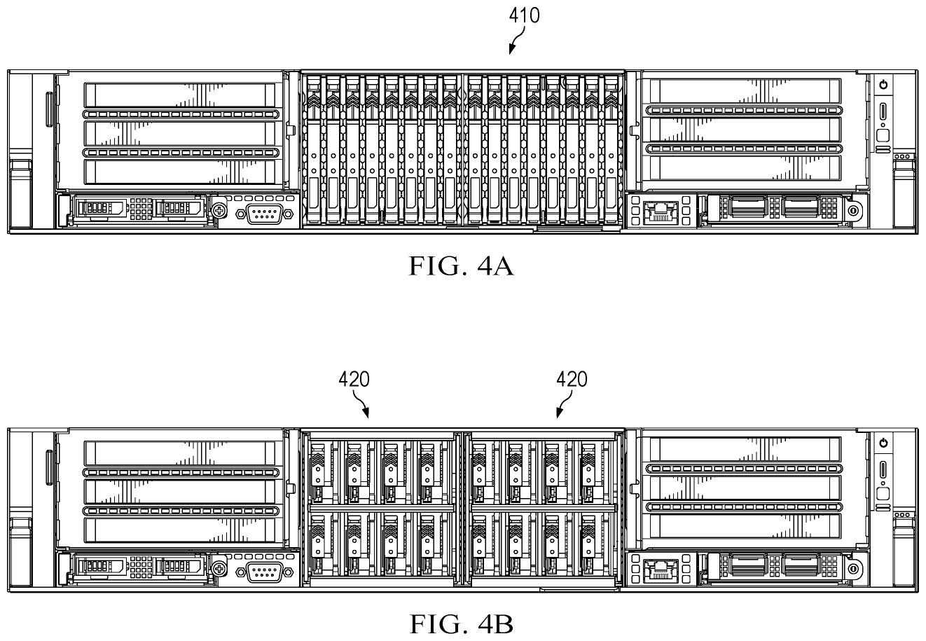

FIGS. 4A and 4B, generally referred to as FIG. 4, show front views of a server type information handling system having a configurable bay device mounting system. More specifically, the configurable bay device mounting system may be configured to mount a plurality of devices 410 conforming to a first form factor (see e.g., FIG. 4A). The configurable device bay mounting system may be configured to mount a plurality of devices 420 conforming to a second form factor (see e.g., FIG. 4B). In certain embodiments, the server type information handling system conforms to a 2 U rack unit height. In certain embodiments, the configurable device bay mounting system may be configured to mount a single row of devices conforming to the first form factor. In certain embodiments, the configurable device bay mounting system may be configured to mount two rows of devices conforming to the first form factor.

In certain embodiments, the first form factor is tall and narrow. In certain embodiments, the second form factor is short and wide. In certain embodiments, the first form factor is substantially (i.e., +/−20%) twice as tall as the second form factor and substantially (i.e., +/−20%) half as wide as the second form factor. In certain embodiments, the second form factor is substantially (i.e., +/−20%) half as tall as the second form factor and substantially (i.e., +/−20%) twice as wide as the second form factor. In certain embodiments, the first form factor corresponds to an EDSFF E3 form factor. In certain embodiments, the second form factor corresponds to an EDSFF E1 form factor.

The configurable bay device mounting system enables configurable drive bay device mounting. In certain embodiments, the configurable drive bay device mounting includes backplane-decoupled disk bay mechanical inserts to optimally arrange the form factors on a server front end. The backplane-decoupled scheme allows any type of backplane to be installed regardless of which insert is assembled. In certain embodiments, the configurable bay device mounting system includes disk bay inserts which slide into place inside the disk bay space. These inserts function as removable dividing partitions which are secured into place with an appropriate number of grooves, notches, and latching features which are common between the insert mechanicals. In certain embodiments, the configurable drive bay device mounting system also includes backplane attachment features associated with respective device bay drive configurations. These backplane attachment features of the disk bay space do not dictate which disk bay inserts could be installed. These two design aspects are independent of each other. The configurable bay device mounting system enables swappable chassis front ends which enable exchange of entire disk bay spaces including backplane mechanicals.

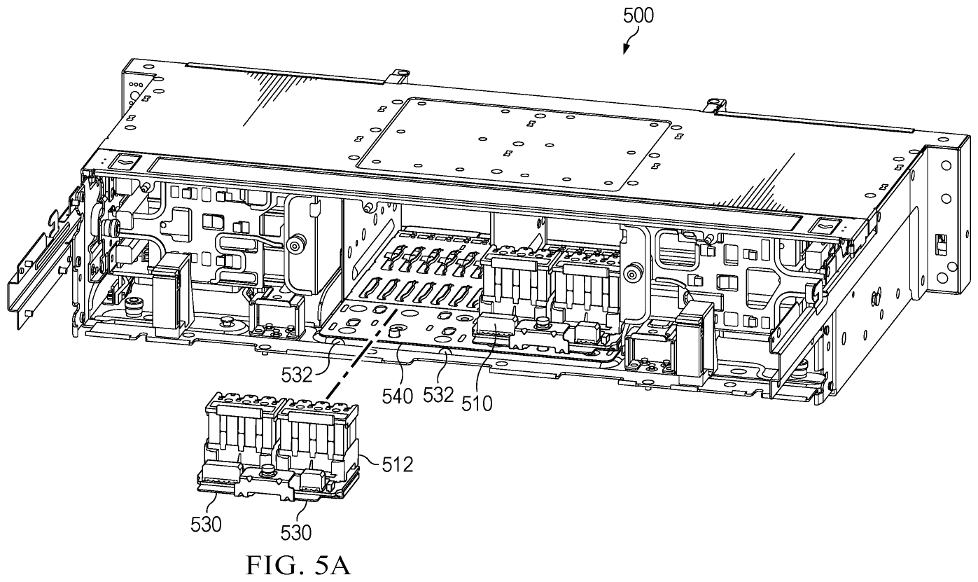

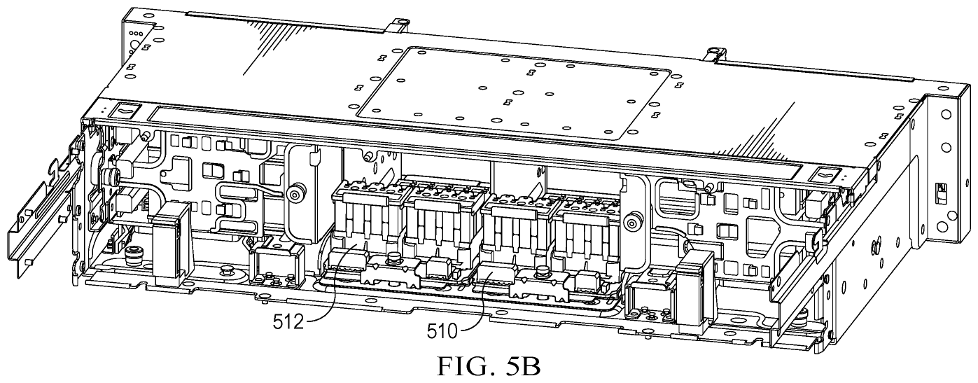

FIGS. 5A and 5B, generally referred to as FIG. 5, show rear perspective views of a modular storage type information handling system 500 having a configurable bay device mounting system. The configurable bay device mounting system enables configurable drive bay device mounting. In certain embodiments, the configurable drive bay device mounting includes backplane-decoupled disk bay components 510, 512 to optimally arrange devices conforming to the first form factor on a server front end. The backplane-decoupled scheme allows any type of backplane to be installed regardless of which insert is assembled. In certain embodiments, the configurable drive bay device mounting system also includes backplane attachment features 530 associated with first form factor device bay drive configuration. These backplane attachment features 530 couple with attachment features 532 of the disk bay space. In certain embodiments, the attachment features 532 of the disk bay space are positioned on a base plate 540 of the disk bay space. These two design aspects are independent of each other. The configurable bay device mounting system enables swappable chassis front ends which enable exchange of entire disk bay spaces including backplane mechanicals.

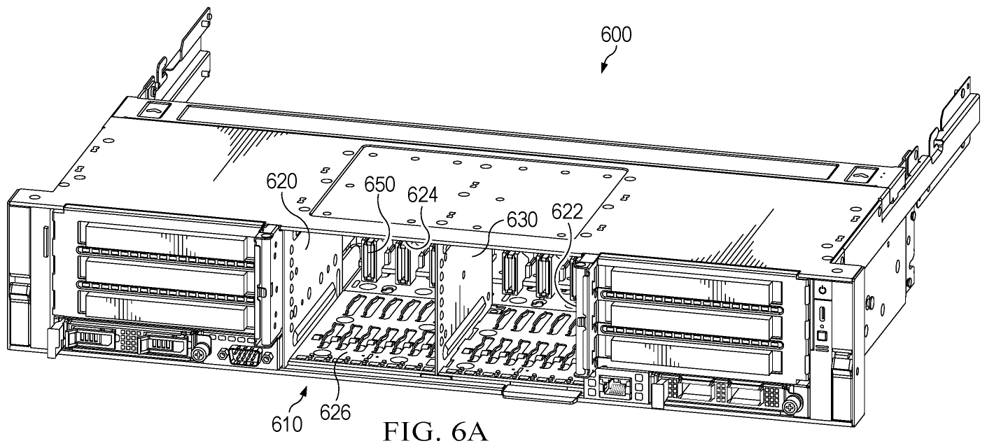

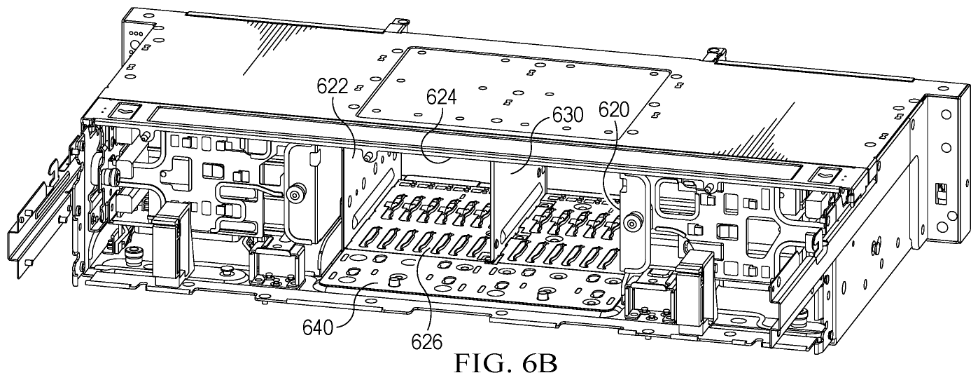

FIGS. 6A and 6B, generally referred to as FIG. 6, show front and rear perspective views of a server type information handling system having a configurable bay device mounting system. In certain embodiments, the configurable bay device mounting system includes a device bay 610. In certain embodiments, the device bay is defined by a first side wall 620, a second side wall 622, a top plate 624 and a bottom plate 626. In certain embodiments, the configurable bay device mounting system includes a disk bay separator insert 630 which slides into place inside the disk bay space. Th disk bay separator insert 630 functions as a removable dividing partition which are secured into place with grooves in the bottom and top of the disk bay 610 space.

In certain embodiments, the configurable drive bay device mounting system includes backplane disk bay connector 650 associated with the first form factor device bay drive configuration. These backplane disk bay mechanical features 650 couple with attachment features 532 included within a rear portion 640 of the bottom plate 626 of the disk bay space.

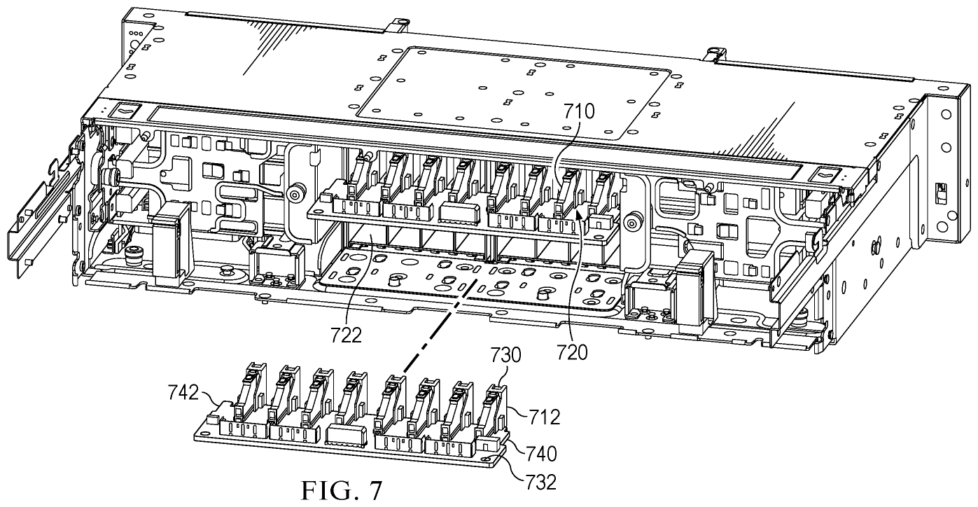

FIG. 7 shows a rear perspective view of a server type information handling system having a configurable bay device mounting system. In certain embodiments, the configurable drive bay device mounting includes backplane-decoupled disk bay mechanical inserts 710, 712 to optimally arrange devices conforming to the second form factor on a server front end. The backplane-decoupled scheme allows any type of backplane to be installed regardless of which insert is assembled. In certain embodiments, the configurable drive bay device mounting system also includes top and bottom backplane elements 730, 732 associated with the device bay drive configuration. In certain embodiments the backplane elements include a backplane connector 730 and a backplane component 742. These backplane attachment features 730 couple with attachment features positioned on a top plate of the disk bay space. In certain embodiments, the backplane mounting plates 740, 742 couple with attachment features of the disk bay space positioned on the side walls of the disk bay space.

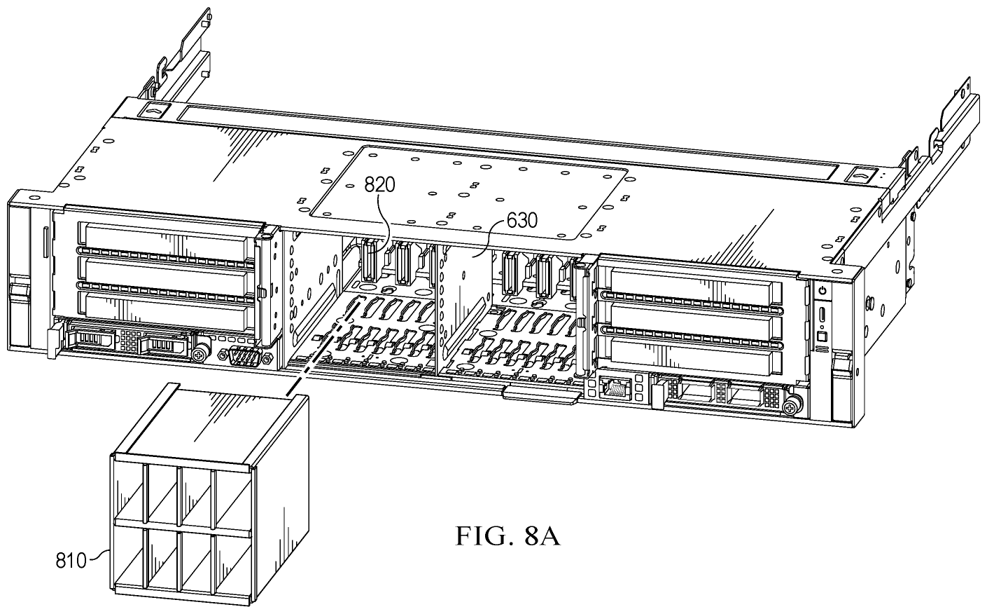

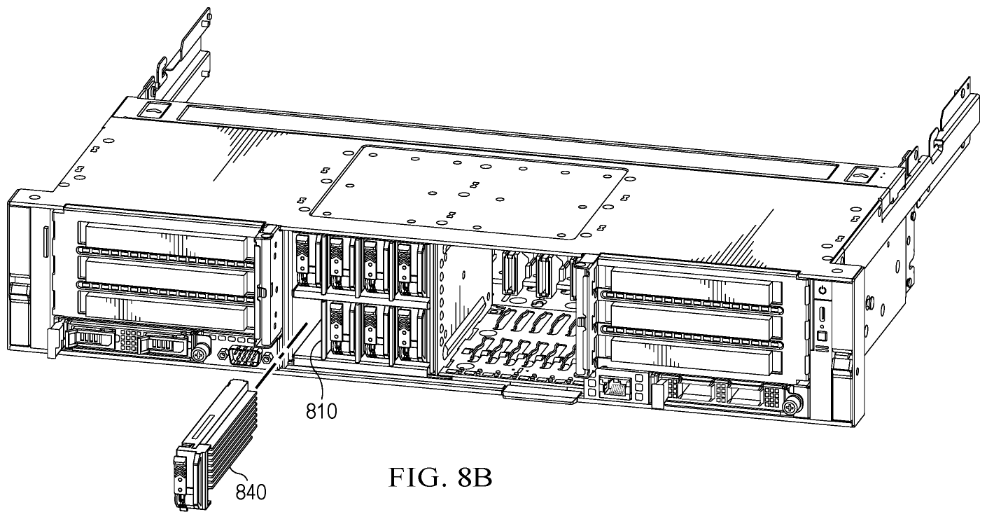

FIG. 8A shows a front perspective view of a server type information handling system having a configurable bay device mounting system. FIG. 8B shows a front perspective view of a server type information handling system having a configurable bay device mounting system.

In certain embodiments, the configurable bay device mounting system includes a disk bay insert 810 which slides into place inside the disk bay space. This insert 810 functions as removable dividing partitions which are secured into place with grooves in the bottom and top of the disk bay space 610. In certain embodiments, the partitions define a plurality of chambers where each chamber corresponds to a respective receiving connector 820 of a device bay mechanical insert. In certain embodiments, the configurable bay device mounting system also includes a disk bay separator insert 630 which slides into place inside the disk bay space. In certain embodiments, the disk bay separator insert 630 divides the disk bay space into a left side and a right side. In certain embodiments, the disk bay insert 810 is mounted between a side wall of the disk bay space and the disk bay separator insert 630.

A plurality of devices 840 are mounted within respective chambers of the disk bay insert 810. The disk bay insert 810 provides mechanical support for each device 840 when the device is mounted within the chamber of the disk bay insert. In certain embodiments, the devices conform to the second form factor. In certain embodiments, the disk bay insert 810 optimally arranges devices conforming to the second form factor on a server front end.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A configurable bay device mounting system, comprising:
a device bay, the device bay, the device bay being defined by a first side wall, a second side wall, a top plate and a bottom plate, the device bay being configurable to mount a plurality of devices conforming to one or both of a first form factor and a second form factor.

2. The configurable bay device mounting system of claim 1, wherein:
the first form factor is substantially twice as tall as the second form factor and substantially half as wide as the second form factor; and,
the second form factor is substantially half as tall as the second form factor and substantially twice as wide as the second form factor.

3. The configurable bay device mounting system of claim 2, wherein:
the first form factor corresponds to an enterprise and datacenter standard form factor (EDSFF) E3 form factor; and,
the second form factor corresponds to an EDSFF E1 form factor.

4. The configurable bay device mounting system of claim 1, further comprising:
one or both of a first backplane disk bay mechanical insert and a second backplane mechanical insert, the first backplane disk bay mechanical insert being configured to couple with a plurality of devices conforming to the first form factor, the second backplane disk bay mechanical insert being configured to couple with a plurality of devices conforming to the second form factor.

5. The configurable bay device mounting system of claim 4, wherein:
the first backplane disk bay mechanical insert and the second backplane disk bay mechanical insert are configured to be attached to a rear portion of the device bay.

6. The configurable bay device mounting system of claim 1, further comprising:
a disk bay insert, the disk bay insert functioning as a removable dividing partition for separating two or more of the plurality of devices.

7. A system comprising:
a processor;
a data bus coupled to the processor;
a configurable bay device mounting system comprising
a device bay, the device bay, the device bay being defined by a first side wall, a second side wall, a top plate and a bottom plate, the device bay being configurable to mount a plurality of devices conforming to one or both of a first form factor and a second form factor.

8. The system of claim 7, wherein:
the first form factor is substantially twice as tall as the second form factor and substantially half as wide as the second form factor; and,
the second form factor is substantially half as tall as the second form factor and substantially twice as wide as the second form factor.

9. The system of claim 8, wherein:
the first form factor corresponds to an enterprise and datacenter standard form factor (EDSFF) E3 form factor; and,
the second form factor corresponds to an EDSFF E1 form factor.

10. The system of claim 7, further comprising:
one or both of a first backplane disk bay mechanical insert and a second backplane mechanical insert, the first backplane disk bay mechanical insert being configured to couple with a plurality of devices conforming to the first form factor, the second backplane disk bay mechanical insert being configured to couple with a plurality of devices conforming to the second form factor.

11. The system of claim 10, wherein:
the first backplane disk bay mechanical insert and the second backplane disk bay mechanical insert are configured to be attached to a rear portion of the device bay.

12. The system of claim 7, further comprising:
a disk bay insert, the disk bay insert functioning as a removable dividing partition for separating two or more of the plurality of devices.
